(19) United States
(12) Patent Application Publication
(10) Pub. No.: US 2008/0318363 A1
(43) Pub. Date: Dec. 25, 2008

(54) Stack circuit member and method

(76) Inventors: Yong-Chai Kwon, Suwon-si (KR); Kang-Wook Lee, Suwon-si (KR); Keum-Hee Ma, Andong-si (KR); Seong-II Han, Suwon-si (KR)

Correspondence Address: HARNESS, DICKEY & PIERCE, P.L.C., P.O. BOX 8910, RESTON, VA, 20195, US

(21) Appl. No.: 12/213,857

(22) Filed: Jun. 25, 2008

Related U.S. Application Data
(62) Division of application No. 11/311,349, filed on Dec. 20, 2005.

(30) Foreign Application Priority Data
Jun. 13, 2005 (KR) 10-2005-50501

(51) Int. Cl. H01L 21/00

(52) U.S. Cl. 438/113; 257/E21.001

(57) ABSTRACT

A stack circuit member may include a first circuit member and a second circuit member. The first and the second circuit members may be electrically and mechanically connected together using a thermocompression bonding method. A photosensitive polymer layer may be interposed between the first circuit member and the second circuit member. A gap fill process and an electrical connection process may be performed at the same time.

### PRIORITY STATEMENT

This U.S. non-provisional application claims benefit of priority under 35 U.S.C. §119 from Korean Patent Application No. 2005-50501, filed on Jun. 13, 2005, the entire contents of which are incorporated herein by reference.

### BACKGROUND

1. Field of the Invention

Example embodiments of the present invention relate in general to a stack circuit member and a method for manufacturing the stack circuit member, and more particularly, to a stack circuit member that may have a photosensitive polymer layer and a method for manufacturing the same.

2. Description of the Related Art

Numerous and varied bonding techniques may be applied to semiconductor chips. Such techniques may include, for example, wire bonding, tape automated bonding (TAB), flip chip bonding, and anisotropic conductive film (ACF) bonding techniques.

It may be desirable to develop methods, techniques and designs that may result in the manufacture of electronic products that are smaller, lighter, faster, more efficient, operate at higher speeds, provide multiple functions and/or result in improved performance, at an effective cost. In an effort to achieve such goals, one method that may be implemented is the flip chip bonding technique.

In an example flip chip bonding technique, a semiconductor chip may be mounted on a wiring substrate by connecting bumps of the semiconductor chip to the wiring substrate. Bumps of the semiconductor chip may be provided on chip pads and may serve as external connection terminals (for example). The bumps may include a solder bump, an Au bump and/or a stud bump, for example. The solder bump and the Au bump may be formed using a plating method (for example) and the stud bump may be formed using a wire bonding method (for example). Numerous and varied bump forming techniques are well known in this art.

The flip chip bonding method may involve a gap fill process (also referred to as an underfill process). The gap fill process may provide a flip chip bonded portion with a filler. The gap fill process may reduce faults. Such faults may result from differences in coefficients of thermal expansion (CTEs) between the semiconductor chip and the wiring substrate, for example. The gap fill process may be implemented via a dispensing method. For example, as shown in FIG. 1, bumps 14 of a semiconductor chip 12 may be connected to a wiring substrate 10 using a flip chip bonding method. A dispenser 16 containing a liquid filler 18 may be located to one side of the semiconductor chip 12. The liquid filler 18 may be dispensed to a flip chip bonded portion between the semiconductor chip 12 and the wiring substrate 10 via the action of a piston 19.

The dispensing method associated with the conventional gap fill process may have associated drawbacks. For example, the filling speed of the filler 18 may be determined by surface tension of the filler 18 between the semiconductor chip 12 and the wiring substrate 10. As the number of the bumps 14 of the semiconductor chip 12 increases, the filling time of the filler 18 and/or the likelihood of voids may also increase. If the gap fill process is performed at a wafer stage, the likelihood of voids may increase.

In an effort to increase the filling speed of the filler, the dispensing method may be performed using injection pressure and/or pulling a vacuum. Although the conventional method is generally thought to be acceptable, it is not without shortcomings. For example, bumps of the semiconductor chip may be swept away by the injection pressure used during the dispensing method. An additional device for supplying injection pressure and/or pulling a vacuum such as a compressor and/or a vacuum pump (for example) may be provided. It may be time consuming to perform a gap fill process on a plurality of wiring substrates. The process time of a gap fill process may be only marginally reduced. The conventional method may nevertheless suffer from gap fill problems.

Further, thermal stresses may occur during a reflow process and/or during a filler curing process. The thermal stresses may be applied to a semiconductor chip, thereby reducing reliability of the semiconductor chip.

The filler may be formed of a film material, for example an ACF and/or a nonconductive film. The film material may not readily spread into a minute gap, thereby resulting in voids, fore example.

### SUMMARY

According to an example, non-limiting embodiment, a stack circuit member may include a first circuit member having an upper surface with connection pads, and a lower surface with bump pads. A second circuit member may be provided on the first circuit member. The second circuit member may have a lower surface with connection bumps. A photosensitive polymer layer may be interposed between the first circuit member and the second circuit member.

According to another example, non-limiting embodiment, a method may involve providing a first circuit member having an upper surface with connection pads and a second circuit member having a lower surface with connection bumps. A photosensitive polymer layer may be provided on at least one of the upper surface of the first circuit member and the lower surface of the second circuit member. The photosensitive polymer layer may be patterned to expose at least one of the connection pads and the connection bumps. The second circuit member may be mounted on the first circuit member. The first and the second circuit members may heated and pressed together to electrically connect the connection bumps of the second circuit member to the connection pads of the first circuit member, and to cure the photosensitive polymer layer.

According to another example, non-limiting embodiment, a semiconductor apparatus may include a wiring substrate having an upper surface with substrate pads. A semiconductor device may be provided on the wiring substrate. The semiconductor device may have connection bumps corresponding to the substrate pads. A photosensitive polymer layer may be interposed between the wiring substrate and the semiconductor device. The photosensitive polymer layer may have windows into which the connection bumps extend.

According to another example, non-limiting embodiment, a method may involve providing a wafer having semiconductor chips. Each semiconductor chip may have an upper surface with connection pads and a lower surface with connection bumps. A wiring substrate may have substrate pads corresponding to the connection bumps. A photosensitive polymer layer may be provided on at least one of the upper surface of the wiring substrate and the lower surface of the wafer. The photosensitive polymer layer may be patterned to expose at least one of the substrate pads and the connection bumps. The wafer may be mounted on the wiring substrate, so that the photosensitive polymer layer may be interposed between the wafer and the wiring substrate, to form a wafer level device. The connection bumps of the wafer may be connected to the substrate pads of the wiring substrate. The wafer level device may be separated into individual semiconductor devices.

According to another example, non-limiting embodiment, a stack circuit member may include a first circuit member having a first conductive element. A second circuit member may be mounted on the first circuit member. The second circuit member may have a second conductive element. A photosensitive polymer layer may be interposed between the first circuit member and the second circuit member. Te first and the second conductive elements may cooperate to form a conductive path through the photosensitive polymer layer.

### BRIEF DESCRIPTION OF THE DRAWINGS

Example, non-limiting embodiments of the present invention will be readily understood with reference to the following detailed description thereof provided in conjunction with the accompanying drawings, wherein like reference numerals designate like structural elements.

FIG. 1 is a cross-sectional view of a conventional gap fill process.

FIG. 2 is a cross-sectional view of a stack circuit member in accordance with an example, non-limiting embodiment of the present invention.

FIGS. 3 through 8 are cross-sectional views of an example, non-limiting method that may be implemented to manufacture the stack circuit member in FIG. 2.

FIGS. 9 through 13 are cross-sectional views of another example, non-limiting method that may be implemented to manufacture the stack circuit member in FIG. 2.

FIG. 14 is a cross-sectional view of a stack circuit member in accordance with another example, non-limiting embodiment of the present invention.

FIGS. 15 through 26 are views of an example method that may be implemented to manufacture the stack circuit member in FIG. 14.

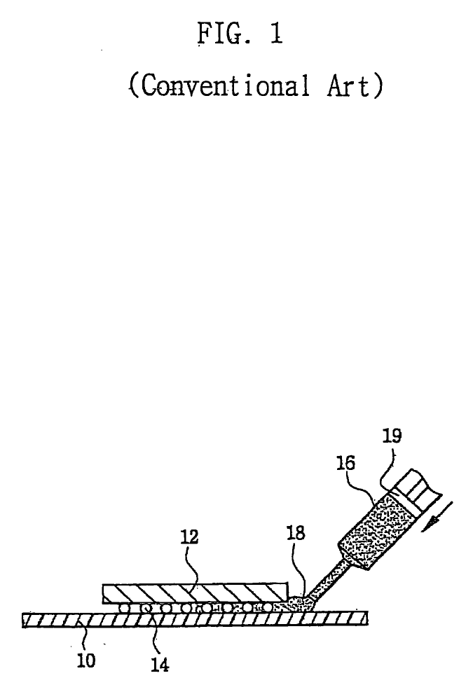

The drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example, non-limiting embodiments of the invention.

### DETAILED DESCRIPTION OF EXAMPLE, NON-LIMITING EMBODIMENTS

Example, non-limiting embodiments of the present invention will be described more fully with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

An element is considered as being mounted (or provided) “on” another element when mounted or provided) either directly on the referenced element or mounted (or provided) on other elements overlaying the referenced element. Throughout this disclosure, spatial terms such as “upper,” “lower,” “above” and “below” (for example) are used for convenience in describing various elements or portions or regions of the elements as shown in the figures. These terms do not, however, require that the structure be maintained in any particular orientation.

Well known structures and processes are not described or illustrated in detail to avoid obscuring the present invention.

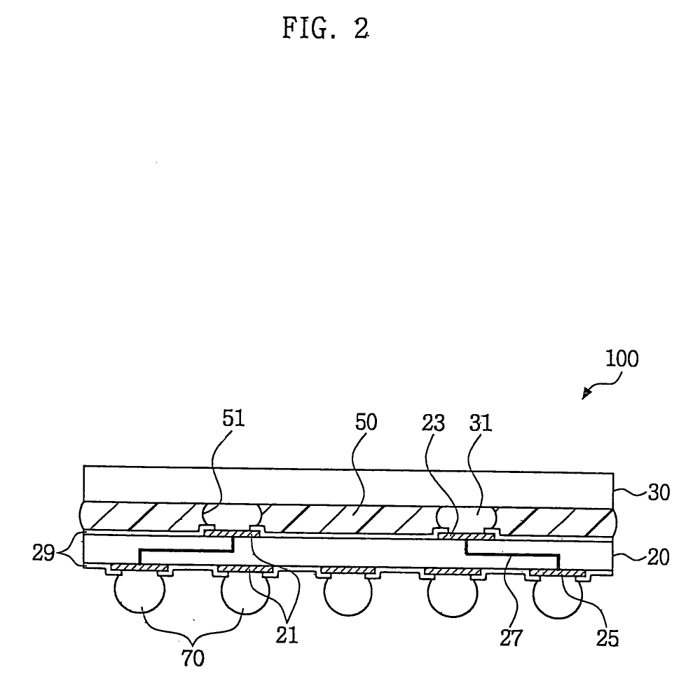

FIG. 2 is a cross-sectional view of a stack circuit member 100 in accordance with an example, non-limiting embodiment of the present invention.

Referring to FIG. 2, the stack circuit member 100 may include a first circuit member 20 having an upper surface and a lower surface, a second circuit member 30 having an upper surface and a lower surface, and a photosensitive polymer layer 50 provided between the first circuit member 20 and the second circuit member 30. Connection pads 23 may be provided on the upper surface of the first circuit member 20. Connection bumps 31 may be provided on the lower surface of the second circuit member 30. The photosensitive polymer layer 50 may be provided on the upper surface of the first circuit member 20. The photosensitive polymer layer 50 may have windows 51, through which the connection pads 23 may be exposed. The windows 51 in the photosensitive polymer layer 50 may be formed using a photolithographic process. The second circuit member 30 may be mounted on the photosensitive polymer layer 50 using a thermocompression bonding process, for example. In this way, the connection bumps 31 may be electrically connected to the connection pads 23. Bump pads 25 may be provided on the lower surface of the first circuit member 20. Solder bumps 70 may be provided on the bump pads 25. The solder bumps may serve as external connection pads, for example.

By way of example only, the first circuit member 20 and the second circuit member 30 may each include a wiring substrate and a semiconductor device. In this example, non-limiting embodiment, the first circuit member 20 may be a wiring substrate, and the second circuit member 30 may be a semiconductor device. Accordingly, the stack circuit member 100 may include a wiring substrate 20 and a semiconductor device 30 provided on the upper surface of the wiring substrate 20. A semiconductor product configured in accordance with this example embodiment may be referred to as a semiconductor apparatus.

The use of the photosensitive polymer layer 50 may facilitate a gap fill process and an electrical connection process. For example, the gap fill process and the electrical connection process may be carried out at the same time.

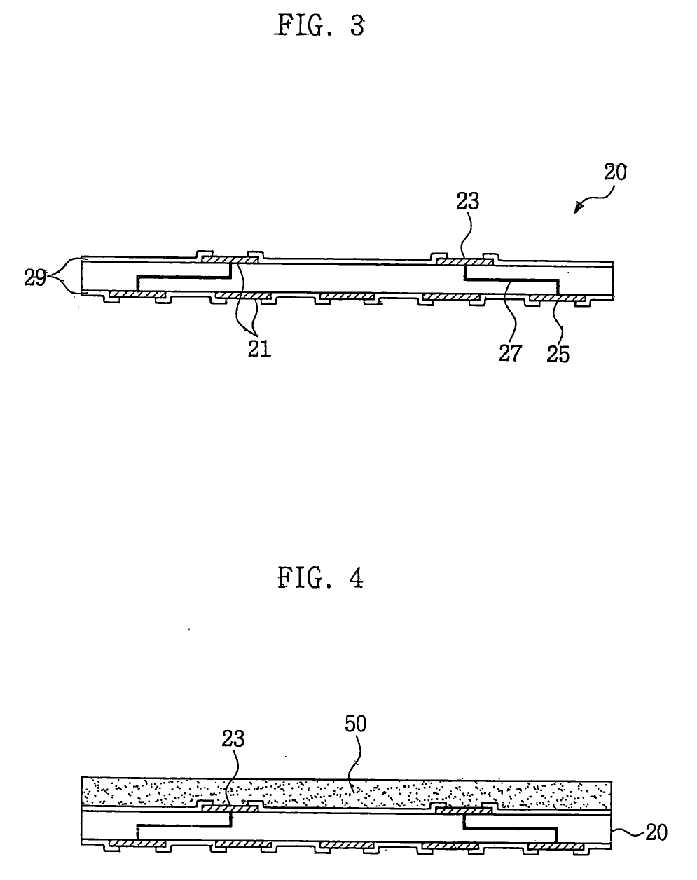

FIGS. 3 through 8 are cross-sectional views of an example, non-limiting method that may be implemented to manufacture the stack circuit member 100 in FIG. 2. The first circuit member may be a wiring substrate 20 and the second circuit member may be a semiconductor device 30.

Referring to FIG. 3, the wiring substrate 20 may have wiring layers 21 provided on the upper surface and the lower surface of the wiring substrate 20. The wiring layers 21 may be fabricated from copper, for example. The wiring layers 21 may include connection pads 23 provided on the upper surface, and bump pads 25 provided on the lower surface. The wiring substrate 20 may be a printed circuit board, for example. The connection pads 23 may be electrically connected to the bump pads 25 using inner wirings 27 and/or vias, for example. A protective layer 29 may cover the wiring layers 21 except for the connection pads 23 and the bump pads 25. The protective layer 29 may be fabricated from a photo solder resist (for example). The protective layer 29 may protect the wiring layer 21 from the external environment, for example.

In alternative embodiments, the wiring substrate 20 may be a tape wiring substrate, a ceramic wiring substrate and/or a silicon wiring substrate, for example. The wiring substrate may be of a strip type so that a plurality of stack circuit members may be produced there from.

Referring to FIG. 4, a photosensitive polymer layer 50 may be provided on the upper surface of the wiring substrate 20. By way of example only, the photosensitive polymer layer 50 may be formed using a spin coating method and/or a dry film attaching method. The spin coating method may involve applying a liquid photosensitive polymer to the upper surface of the wiring substrate 20. The dry film attaching method may involve attaching a photosensitive polymer film to the upper surface of the wiring substrate 20.

The thickness of the photosensitive polymer layer 50 may correspond to a gap between the wiring substrate 20 and the semiconductor device 30.

By way of example only, the photosensitive polymer may include a thermosetting polymer, which may contain a photo active component. The thermosetting polymer may include an epoxy, a polyimide, and/or a novolak resin, for example. Numerous and varied photo active components, which are well known in this art, may be suitably implemented.

By way of example only, the thermosetting polymer may have a hard curing temperature equal or similar to a bonding temperature of bonding the connection pads 23 to connection bumps 31. In alternative embodiments, the hard curing temperature of the thermosetting polymer may be different than (and/or independent of) the bonding temperature of bonding the connection pads 23 to the connection bumps 31.

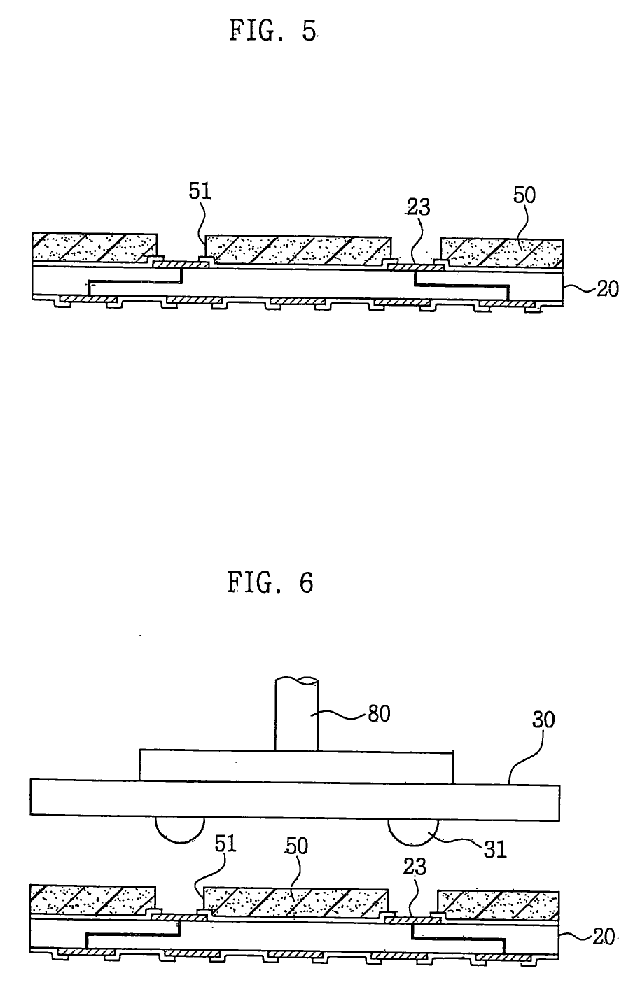

Referring to FIG. 5, the photosensitive polymer layer 50 may be patterned to form windows 51, through which the connection pads 23 may be exposed. Because the photosensitive polymer layer 50 itself has photosensitivity, the photosensitive polymer layer 50 may be patterned without a photo mask for patterning. The photosensitive polymer layer 50 may be patterned using conventional photolithographic techniques that are well known in this art.

The patterned photosensitive polymer layer 50 may be flowable. External pressure applied to the photosensitive polymer layer 50 may damage the photosensitive polymer layer 50. For example, external pressure may inadvertently deform the windows 51. The photosensitive polymer layer 50 may be strengthened via a partial curing process. The partial curing process may be referred to as a soft curing process. A subsequent curing process for completely curing the photosensitive polymer layer 50 may be referred to as a hard curing process. In alternative embodiments, the soft curing process may be altogether omitted.

The soft curing process may be performed at a lower temperature than the hard curing process, for example at a temperature as low as one third to one half of the hard curing process temperature. By way of example only, when the temperature of the hard curing process is about 150° C., the temperature of the soft curing process may be about 100° C.

Referring to FIG. 6, the semiconductor device 30 may be superposed over the wiring substrate 20. The semiconductor device 30 may have connection bumps 31 provided on the lower surface. The connection bumps 31 may correspond to the connection pads 23 of the wiring substrate 20. The connection bumps 31 of the semiconductor chip 30 may be aligned with the connection pads 23 of the wiring substrate 20.

The semiconductor device 30 may include a semiconductor chip having connection bumps formed directly on chip pads, and a BGA package including a chip scale package having connection bumps formed using redistribution lines. Numerous and varied semiconductor devices, which are well known in this art, may be suitably implemented.

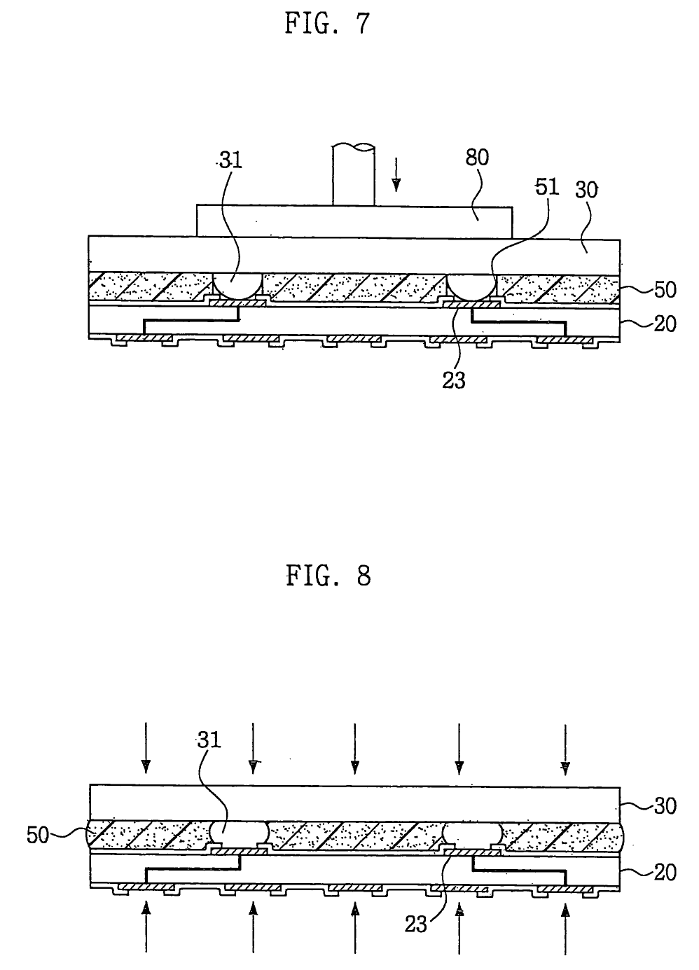

Referring to FIG. 7, the semiconductor device 30 may be mounted on the photosensitive polymer layer 50.

For example, a transfer device 80 may support (via suction, for example) an upper surface of the semiconductor device 30. The transfer device 80 may align the semiconductor device 30 above the wiring substrate 20 and mount the semiconductor device 30 on the photosensitive polymer layer 50. The connection bumps 31 of the semiconductor device 30 may be inserted into the windows 51 of the photosensitive polymer layer 50.

When the semiconductor device 30 is mounted on the photosensitive polymer layer 50, a pressing force may be applied to the semiconductor device 30. The application of pressing force may increase the adhesion of the semiconductor device 30 to the wiring substrate 20. Such adhesion may reduce the likelihood of separation of the component parts, when the assembly (inclusive of the wiring substrate 20 and the semiconductor device 30) is moved and/or handled. For example, the assembly may be moved to a thermocompressor for a subsequent process.

Referring to FIG. 8, a thermocompression bonding process may be performed. Under temperature conditions by which the photosensitive polymer layer 50 may be hard cured, a compressing force may be applied to the semiconductor device 30. The connection bumps 31 of the semiconductor device 30 may be connected to the connection pads 23 of the wiring substrate 20. The process conditions may be such that the connection bumps 31 reflow and/or change shape. The photosensitive polymer layer 50 may penetrate into voids that may exist around the connection bumps 31 and be hard cured.

To enhance a connection of the connection bumps 31 to the connection pads 23, a solder layer (not shown) may be provided on the connection pads 23.

An adhesion promoter may be applied to the lower surface of the semiconductor device 30 to enhance an adhering strength of the semiconductor device 30 to the photosensitive polymer layer 50. The adhesion promoter may include a vinylthree acetoxysilane, for example.

Returning to FIG. 2, solder bumps 70 may be provided on the bump pads 25 of the wiring substrate 20. In this example embodiment, the solder bumps 70 may have a spherical shape. In alternative embodiments, the solder bumps 70 may have any other geometric shape.

According to the example, non-limiting method of the present invention, the semiconductor device 30 may be mounted on the wiring substrate 20 by aligning the semiconductor device 30 with the wiring substrate 20 and inserting the connection bumps 31 into the windows 51 of the photosensitive polymer layer 50. The example method may eliminate some conventional mounting processes, for example a fluxing process and a flux cleaning process.

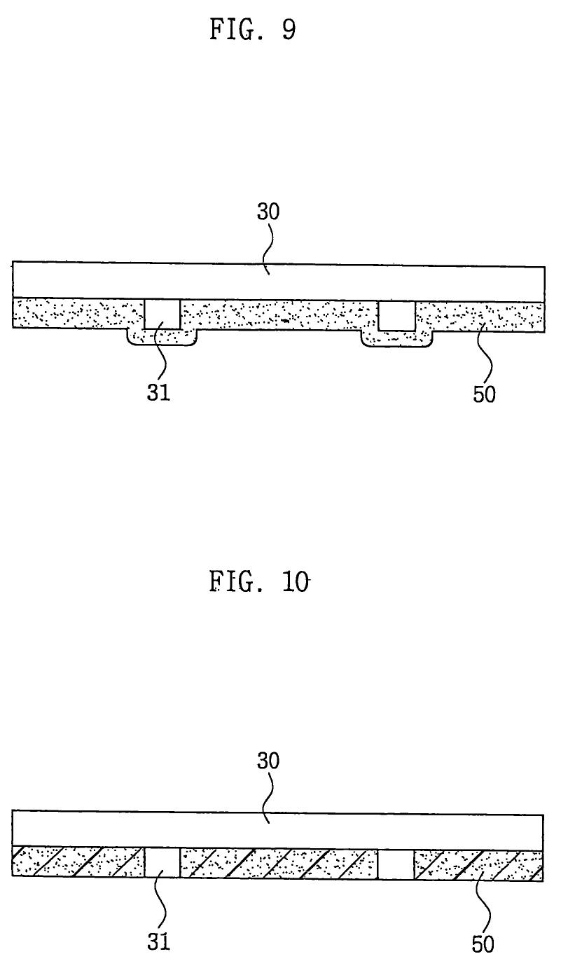

Although this example embodiment shows the photosensitive polymer layer 50 provided on the upper surface of the wiring substrate 20, the photosensitive polymer layer 50 may be provided on the lower surface of the semiconductor device 30, as shown in FIGS. 9 through 13.

FIGS. 9 through 13 are cross-sectional views of another example method that may be implemented to manufacture the stack circuit member 100 in FIG. 2.

As shown in FIG. 9, the photosensitive polymer layer 50 may be provided on the lower surface of the semiconductor device 30, which may include connection bumps 31. As shown in FIG. 10, the photosensitive polymer layer 50 may be patterned to expose the connection bumps 31. The photosensitive polymer layer 50 may be soft cured. In alternative embodiments, the soft curing may be altogether omitted.

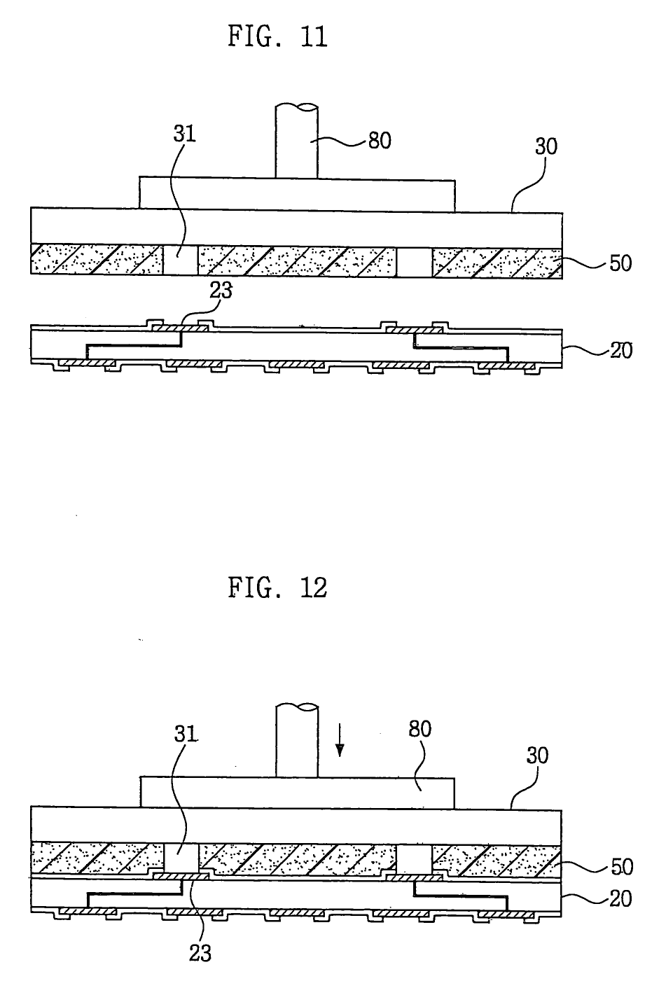

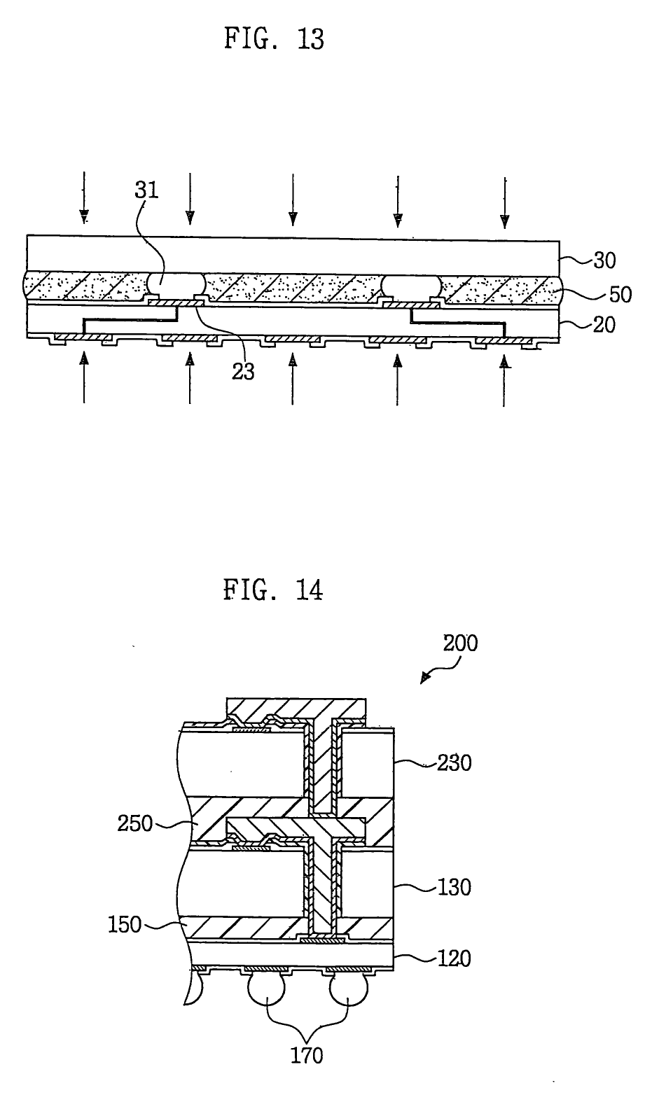

Referring to FIGS. 11 through 13, the semiconductor device 30 may be mounted on the wiring substrate 20 using a thermocompression bonding method that may be similar to the one described with respect to the previous embodiment. Briefly, the semiconductor device 30 may be aligned with the wiring substrate 20 so that the connection bumps 31 of the semiconductor device 30 may correspond to the connection pads 23 of the wiring substrate 20, as shown in FIG. 11. A pressing force may be applied to the semiconductor device 30, as shown in FIG. 12. The connection bumps 31 may be electrically connected to the connection pads 23, as shown in FIG. 13.

Referring to FIG. 2, solder bumps 70 may be provided on the lower surface of the wiring substrate 20.

The method according to this example embodiment may proceed in the same manner as the above described embodiment, except that the photosensitive polymer layer 50 may be provided on the lower surface of the semiconductor device 30.

In another example, non-limiting embodiment, a photosensitive polymer layer 50 may be provided on both the upper surface of the wiring substrate 20 and the lower surface of the semiconductor device 30. In this case, the thickness of the photosensitive polymer layer 50 may be substantially the same as the height of the connection bumps 31 after a thermocompression bonding process.

The photosensitive polymer layer 50 may be used in mounting the semiconductor device on a mounting substrate.

FIG. 14 is a cross-sectional view of a stack circuit member 200 in accordance with another example, non-limiting embodiment of the present invention.

Referring to FIG. 14, the stack circuit member 200 may include a first circuit member 120 and two second circuit members 130 and 230 that may be stacked on the first circuit member 120. A photosensitive polymer layer 150 may be provided between the first circuit member 120 and the second circuit member 130. A photosensitive polymer layer 250 may be provided between the second circuit members 130 and 230. Solder bumps 170 may be provided on the lower surface of the first circuit member 120. The solder bumps may serve as external connection terminals, for example.

In this example embodiment, the first circuit member 120 may be a wiring substrate. The second circuit members 130 and 230 may be chip scale packages. The second circuit members 130 and 230 may be provided (and assembled together) in wafer form. Each wafer may have a plurality of chip scale packages.

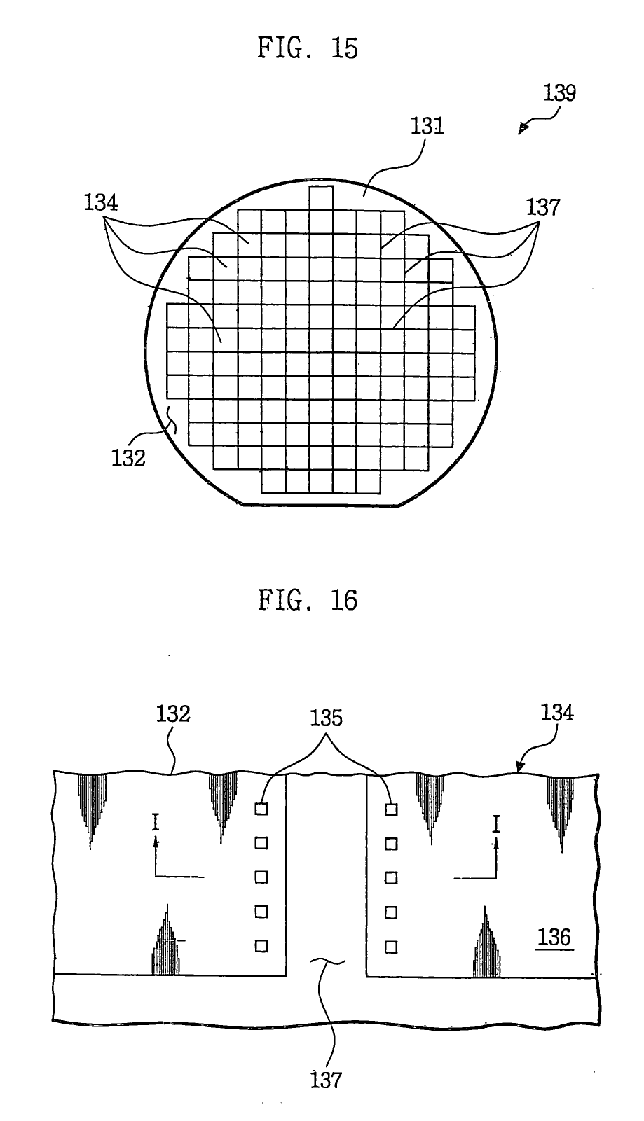

FIGS. 15 through 26 illustrate an example, non-limiting method that may be implemented to manufacture the stack circuit member 200 in FIG. 14. A photosensitive polymer layer may be provided on at least one of a wafer surface and a wiring substrate surface. In this example embodiment, a photosensitive polymer layer may be provided on a lower surface of the wafer.

Referring to FIG. 15, a wafer 139 having an upper surface 132 and a lower surface 133 may be provided. A silicon substrate 131 may have a plurality of integrated circuits. The integrated circuits may form semiconductor chips 134. Scribe lines 137 may be provided between adjacent semiconductor chips 134. Integrated circuits are well known in this art, and therefore a detailed description of the same is omitted.

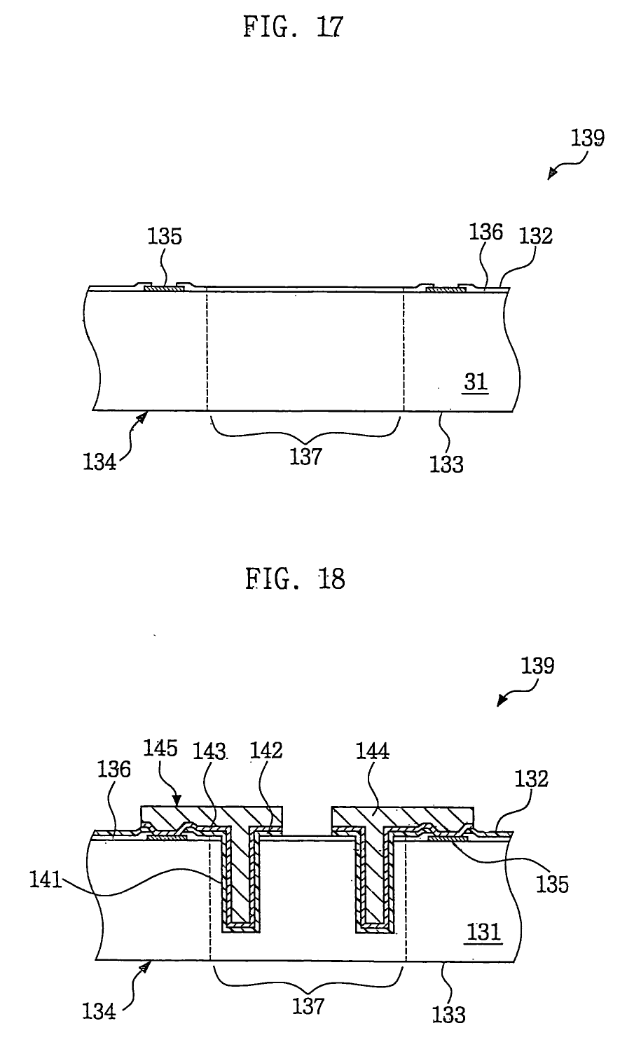

Referring to FIGS. 16 and 17, chip pads 135 may be provided on the upper surface 132 of the silicon substrate 131. The chip pads 135 may be electrically connected to the integrated circuits. A passivation layer 136 may be provided on the upper surface 132 of the silicon substrate 131. The passivation layer 136 may protect the integrated circuits from the external environment, for example. The chip pads 135 may be exposed through the passivation layer 136. The chip pads 135 may be fabricated from Al (for example) and the passivation layer 136 may be fabricated from oxide, nitride and/or an alloy thereof, for example. Although this example embodiment shows the chip pads 135 arranged along the edges of the semiconductor chip 134, the chip pads 135 may be not limited in this regard.

Referring to FIG. 18, electrodes 145 may be provided. For example, connection holes 141 may be provided in the scribe line 137. The connection hole 141 may be located adjacent to the chip pads 135. A dielectric layer 142 may be provided on the inner walls of the connection hole 141 and on the passivation layer 136. The dielectric layer 142 may be patterned to expose the chip pads 135. The dielectric layer 142 may be fabricated from nitride, for example.

A metal barrier layer 143 may be provided on the dielectric layer 142. A metal wiring layer 144 may be provided on the metal barrier layer 143 and connected to the chip pads 135. The metal barrier layer 143 may facilitate a formation of the metal wiring layer 144 on the dielectric layer 142.

By way of example only, the metal wiring layer 144 may be formed by an electroplating method using the metal barrier layer 143 as a plating electrode, or by a selective deposition method. Of course numerous other and alternative forming techniques that are well known in this art may be suitably implemented. The metal wiring layer 144 may be fabricated from Cu, Al, an alloy thereof, or other conductive materials, for example.

The electrodes 145 may be provided by numerous and alternative methods that are well known in this art.

In this example embodiment, the electrodes 145 may be located in the scribe line 137. In alternative embodiments, the electrode may be provided at other locations. For example, the electrodes 145 may penetrate the chip pads 135.

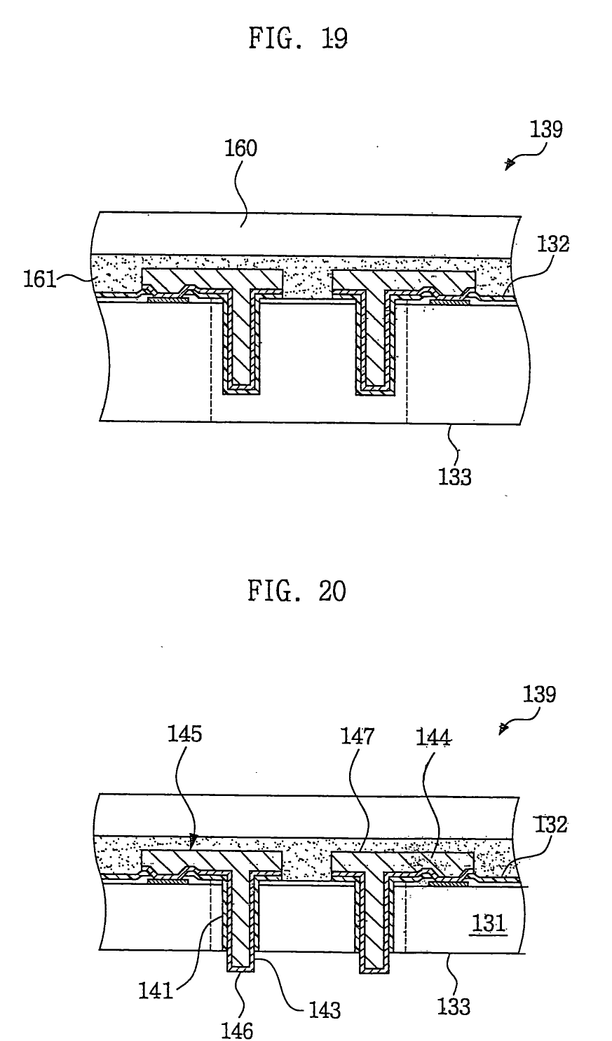

Referring to FIG. 19, a support substrate 160 may be provided on the upper surface 132 of the wafer 139. The support substrate 160 may relieve stresses that may be applied to the wafer 139 during a thinning process, for example. The support substrate 160 may also suppress warpage of the wafer 139 after the thinning process, for example.

The support substrate 160 may be fabricated from materials having similar or the same CTE as the wafer 139, for example silicon and/or glass. The support substrate 160 may be a circular plate corresponding to the shape of the wafer 139.

The support substrate 160 may be provided on the upper surface 132 of the wafer 139 using an adhesive. By way of example only, the adhesive may be a reworkable adhesive 161. The reworkable adhesive 161 may include an ultraviolet adhesive and/or a thermoplastic adhesive, for example.

Referring to FIG. 20, the wafer 139 may be thinned. A portion of the lower surface 133 of the wafer 139 may be removed using a grinding method, for example. The ground lower surface 133 of the wafer 139 may be approximately level with a lower end of the electrode 145. The silicon substrate 131 may be selectively etched from the ground lower surface 133, so that a portion of the electrode 145 may be exposed. As illustrated, a portion of the electrode 145 may project from the silicon substrate.

By way of example only, the initial thickness of the wafer 139 may be about 700 μm and the thickness of the thinned wafer 139 may be 100 μm or less. A further thinning process may be suitably implemented.

The exposed portion of the electrode 145 may serve as a connection bump 146. The metal wiring layer 144 may serve as a connection pad 147.

The thicknesses of the connection holes 141 may be varied from one connection hole to the next. The exposed metal barrier layer 143 covering the outer surface of the connection bumps 146 may be formed using a sputtering method (for example), and therefore the exposed metal barrier layer 143 may have an irregular shaped end. The irregular shaped end of the metal barrier layer 143 may reduce the connection reliability between the connection bump 146 and a substrate pad of a wiring substrate.

A planarization process may be implemented to level the height of the connection bumps 146. The planarization process may improve contact areas between the connection bump 146 and the substrate pad to improve a connection between the connection bump 146 and the substrate pad. The planarization process may use a chemical polishing method and/or a mechanical polishing method, for example.

Two wafers may be stacked on a wiring substrate. A lower wafer may be referred to as a first wafer 139 and an upper wafer as a second wafer 239.

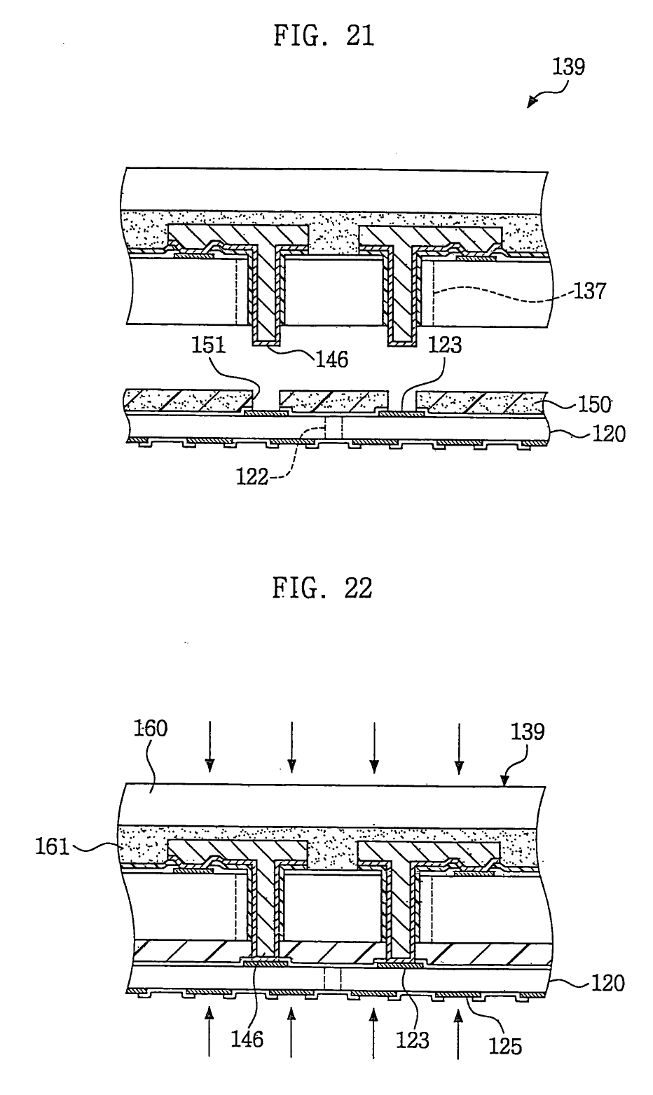

Referring to FIGS. 21 and 22, the first wafer 139 may be mounted on a wiring substrate 120. As shown in FIG. 21, the wiring substrate 120 may have a first photosensitive polymer layer 150. The first wafer 139 may be aligned with the wiring substrate 120 so that first connection bumps 146 of the first wafer 139 may correspond to substrate pads 123 of the wiring substrate 120. The photosensitive polymer layer 150 may be provided in the same manner as in the previously described embodiments. The wiring substrate 120 may be a circular plate corresponding to the shape of the first wafer 139. The wiring substrate 120 may have scribe lines 122 corresponding to the chip scribe lines 137 of the first wafer 139. The wiring substrate 120 may include a printed circuit board, a tape wiring substrate, a ceramic substrate, and/or a silicon substrate, for example.

As shown in FIG. 22, the first wafer 139 may be mounted on the wiring substrate 120 using a thermocompression bonding method, for example. By way of example only, a gap fill process and an electrical connection process may be simultaneously performed.

A solder layer may be provided on the substrate pads 123. The solder layer may facilitate a connection of the connection bumps 146 to the substrate pads 123. An adhesion promoter may be applied to the lower surface 133 of the first wafer 139. The adhesion promoter may improve adhesion of the lower surface 133 of the first wafer 139 to the first photosensitive polymer layer 150.

The wiring substrate 120 having the first wafer 139 may be diced into individual stack circuit members after a solder bump attaching process. The dicing process may be carried out via sawing, for example. The stack circuit member may form a chip scale package having a single semiconductor chip, as in the above-described embodiment.

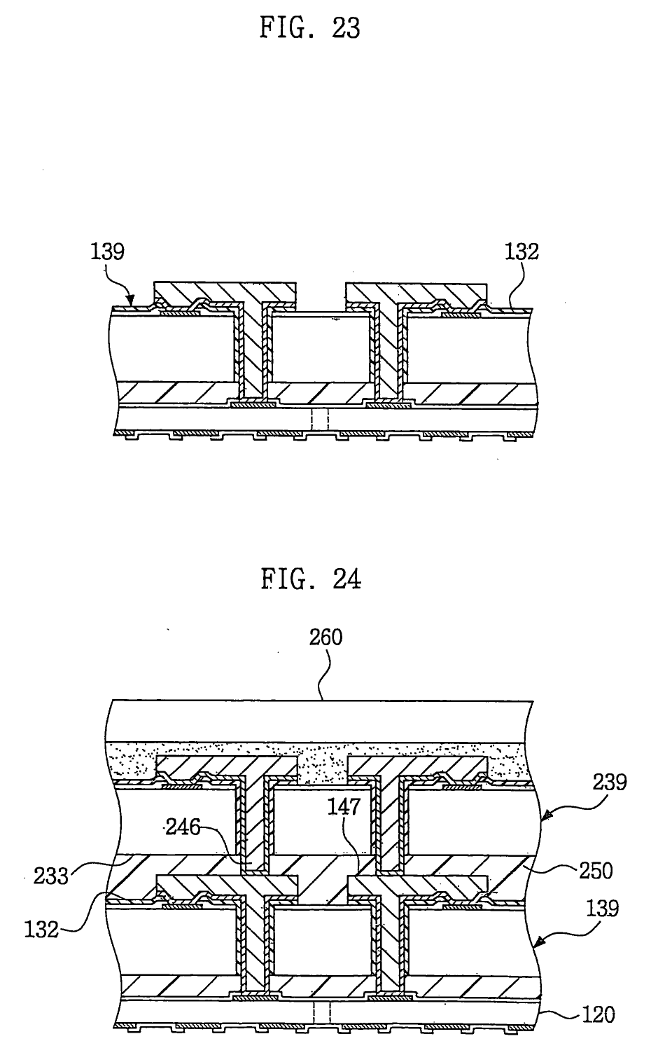

Referring to FIG. 23, the first support substrate 160 of the first wafer 132 may be removed. If an ultraviolet tape is used as the reworkable adhesive 161, then ultraviolet rays may be applied to separate the first support substrate 160 from the first wafer 139. If a thermoplastic adhesive is used as the reworkable adhesive 161, then heat may be applied to separate the first support substrate 160 from the first wafer 139. The thermoplastic adhesive which may remain on the first wafer 132 may be removed using an O₂ ashing process, for example.

Referring to FIG. 24, the second wafer 239 may be stacked on the first wafer 139. The stacking process may be performed in a similar manner as the mounting of the first wafer 139 on the wiring substrate 120. A second photosensitive polymer layer 250 may be provided on the upper surface 132 of the first wafer 139. Second connection bumps 246 of the second wafer 239 may be connected to the first connection pads 147 of the first wafer 139 using a thermocompression bonding method, for example. The second photosensitive polymer layer 250 may fill gaps between the first wafer 139 and the second wafer 239.

Although this example embodiment shows two wafers 139 and 239, three or more wafers may be stacked on the wiring substrate 120.

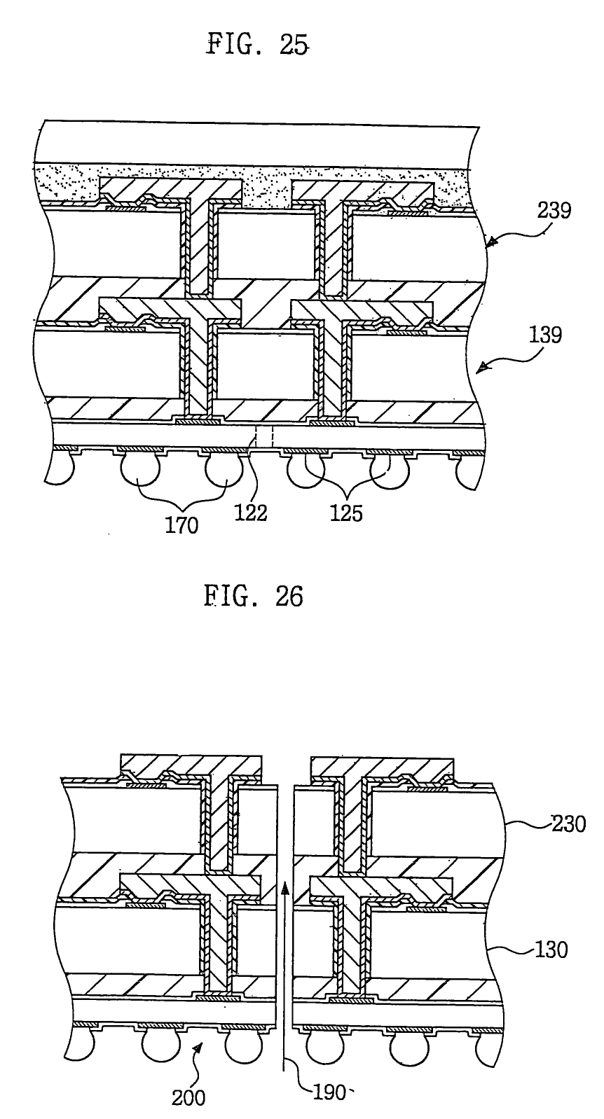

Referring to FIG. 25, solder bumps 170 may be provided on bump pads 125 of the lower surface of the wiring substrate 120.

Referring to FIG. 26, the second support substrate 260 may be removed. The stacked wafers may be diced into individual stack circuit members 200. The stacked wafers may be diced (for example) by sawing along the scribe lines 122 using a sawing apparatus 190.

The sawing process may use a wafer tape and/or a fixing device for fixing the stacked wafers.

In accordance with the example, non-limiting embodiments of the present invention, a photosensitive polymer layer may be provided on at least one of the upper surface of the first circuit member and the lower surface of the second circuit member. The second circuit member may be stacked on the first circuit member via a thermocompression bonding method (for example) with the photosensitive polymer layer filling gaps therebetween.

Although example, non-limiting embodiments of the present invention have been described in detail, it will be understood that many variations and/or modifications of the basic inventive concepts, which may appear to those skilled in the art, will still fall within the spirit and scope of the example embodiments of the present invention as defined in the appended claims.

1.-7. (canceled)

8. A method comprising:
providing a first circuit member having an upper surface with connection pads and a second circuit member having a lower surface with connection bumps;
providing a photosensitive polymer layer on at least one of the upper surface of the first circuit member and the lower surface of the second circuit member;
patterning the photosensitive polymer layer to expose at least one of the connection pads and the connection bumps;
mounting the second circuit member on the first circuit member; and
heating and pressing together the first and the second circuit members to connect the connection bumps of the second circuit member to the connection pads of the first circuit member, and cure the photosensitive polymer layer.

9. The method of claim 8, wherein providing the photosensitive polymer layer includes applying a liquid photosensitive polymer using a spin-on method.

10. The method of claim 8, wherein providing the photosensitive polymer layer includes attaching a photosensitive polymer film.

11. The method of claim 8, wherein the photosensitive polymer layer is provided on only one of the upper surface of the first circuit member and the lower surface of the second circuit member.

12. The method of claim 11, further comprising applying an adhesion promoter on one of the upper surface of the first circuit member and the lower surface of the second circuit member on which the photosensitive polymer layer is not provided.

13. The method of claim 11, wherein the thickness of the photosensitive polymer layer is substantially equal to a gap between the first circuit member and the second circuit member.

14. The method of claim 8, further comprising soft curing the photosensitive polymer layer prior to mounting the second circuit member on the first circuit member, wherein the temperature of the soft curing is lower than the temperature of the curing that occurs during heating and pressing together the first and the second circuit members.

15.-20. (canceled)

21. A method comprising:
providing a wafer having semiconductor chips, each semiconductor chip having an upper surface with connection pads and a lower surface with connection bumps;
providing a wiring substrate having substrate pads corresponding to the connection bumps;
providing a photosensitive polymer layer on at least one of the upper surface of the wiring substrate and the lower surface of the wafer;
patterning the photosensitive polymer layer to expose at least one of the substrate pads and the connection bumps;
mounting the wafer on the wiring substrate, so that the photosensitive polymer layer is interposed between the wafer and the wiring substrate, to form a wafer level device;
connecting the connection bumps of the wafer to the substrate pads of the wiring substrate; and
separating the wafer level device into individual semiconductor devices.

22. The method of claim 21, wherein providing a wafer comprises:
providing a wafer having an upper surface with chip pads and a lower surface;
providing holes in the wafer;
providing a dielectric layer on inner walls of the holes and on the upper surface of the wafer, so that the chip pads are exposed through the dielectric layer;
providing a metal wiring layer in the holes, the metal wiring layer electrically connected to the chip pads; and
removing the lower surface of the wafer to provide the connection bumps,
wherein a portion of the metal wiring layer serves as the connection pads.

23. The method of claim 22, wherein providing the connection bumps comprises:
providing a support substrate on the wafer using an adhesive.

24. The method of claim 23, wherein the support substrate is fabricated from at least one of silicon and glass having a coefficient of thermal expansion that is substantially equal to that of the wafer.

25. The method of claim 23, wherein the adhesive includes one of a thermoplastic adhesive and an ultraviolet adhesive.

26. The method of claim 23, further comprising planarizing the connection bumps.

27. The method of claim 23, further comprising providing external connection terminals on the lower surface of the wiring substrate before separating the wafer level device into individual semiconductor devices.

28. The method of claim 23, further comprising separating the individual semiconductor devices from the support substrate.

29. The method of claim 23, further comprising removing the support substrate before separating the wafer level device into individual semiconductor devices.

30. The method of claim 29, further comprising:
stacking at least one wafer on the upper surface of the wafer using a photosensitive polymer layer after removing the support substrate,
repeat stacking at least one wafer and removing the support substrate until an uppermost wafer is stacked.

31. The method of claim 30, wherein stacking at least one wafer comprises:
providing a photosensitive polymer layer on at least one of the upper surface of a lower wafer and the lower surface of an upper wafer;
patterning the photosensitive polymer layer to expose at least one of connection pads of the lower wafer and connection bumps of the upper wafer;
mounting the upper wafer on the lower wafer; and
connecting the connection bumps of the upper wafer to the connection pads of the lower wafer.

32. The method of claim 31, wherein external connection terminals are provided on the lower surface of the wiring substrate before separating the wafer level device into individual semiconductor devices.

33. The method of claim 32, wherein a support substrate of the uppermost wafer is removed before separating the wafer level device into individual semiconductor devices.

34. The method of claim 21, further comprising:
soft curing the photosensitive polymer layer before mounting the wafer on the wiring substrate.

35. (canceled)
